(19) United States
(12) Patent Application Publication
(10) Pub. No.: US 2014/0230553 A1
(43) Pub. Date: Aug. 21, 2014

(54) Method of Detecting Movement Using a Metallic Conductors

(71) Applicant: Network Integrity Systems, Inc., (US)

(72) Inventors: David E. Vokey, Sidney (CA); Cary R. Murphy, Hickory, NC (US); Mark K. Bridges, Hickory, NC (US); Joseph Giovannini, Hickory, NC (US); Daniel Goertzen, Winnipeg (CA)

(73) Assignee: NETWORK INTEGRITY SYSTEMS, INC., Hickory, NC (US)

(21) Appl. No.: 13/771,901

(22) Filed: Feb. 20, 2013

(51) Int. Cl. G01R 27/26; G01H 13/00; G01H 11/06

(52) U.S. Cl. CPC G01R 27/2605; G01H 11/06; G01H 13/00
USPC 73/579; 324/658; 73/658

(57) ABSTRACT

A method for monitoring movement of an element such as a cable is carried out by providing a pair of conductive elements each extending along an extent of the cable or other element to be monitored. A DC potential difference is applied between the conductive elements. The conductive elements are provided with an intervening material therebetween, which can be a continuous dielectric or can be other insulating material which varies in spacing and capacitance value along its length, such that the movement causes a change in capacitive coupling between the conductive elements at points or areas where the movement occurs so as to generate a changing voltage therebetween. The changing voltage as an amplified and filtered variable electrical signal is analyzed for monitoring the changing voltage for perturbations caused by the movement of the element.

The present invention relates to the detection of movement of a cable containing conductive elements.

The present invention as described in more detail hereinafter operates by monitoring and analyzing the perturbation of an electric potential difference between two separate conductors in a cable. This detection of movement can be used in many fields but is particularly directed to a method which allows the detection of an intrusion event for purposes of securing the cable against unauthorized tampering.

### BACKGROUND OF THE INVENTION

Gigabit Ethernet copper cables are frequently deployed to provide high-speed networks within buildings. Copper based cables, while bandwidth and distance limited as compared to fiber optic cables, are electrically compatible with the Ethernet ports on most computers. As a result, even when fiber optic cable are used as the backbone of the network, the choice is often made to switch to copper cables for the last few hundred feet to the desk.

To secure the fiber optic portion of these high-speed networks, Fiber Optic Intrusion Detection Systems (FOIDS) have been introduced that turns fibers inside of the cables into “sensors” that monitor the physical security of the cable or cables. Thus, once employed, the FOIDS is constantly looking for any potential tampering or attempts to access the fibers inside of the cable or cables.

That is the detection of movement of fiber optic cables has been carried out by sending optical signals into the fiber for transmission therealong, by extracting from the fiber light signals caused by the transmission and by analyzing those signals to obtain information indicative of changes in the signals caused by the movement.

A product for this purpose is sold by the present Assignees under the trademarks Interceptor and Vanguard, details of which are available from a number of prior issued patents by the Assignees including U.S. Pat. No. 7,333,681 (Murphy) issued Feb. 19, 2008 which describes a system for securing multimode fibers and U.S. Pat. No. 7,142,737 (Murphy) issued Nov. 28, 2006 which describes a system for securing single mode fibers. Reference also is made to the following patents:

U.S. Pat. No. 8,233,755 Jul. 31, 2012

U.S. Pat. No. 8,094,977 Jan. 10, 2012

U.S. Pat. No. 7,693,359 Apr. 6, 2010

U.S. Pat. No. 7,706,641 Apr. 27, 2010

U.S. Pat. No. 7,634,387 Dec. 15, 2009

U.S. Pat. No. 7,403,675 Jul. 22, 2008

U.S. Pat. No. 7,376,293 May 20, 2008

U.S. Pat. No. 7,206,469 Apr. 17, 2007

U.S. Pat. No. 7,120,324 Oct. 10, 2006

This arrangement has provided a signal analysis system which is very effective at analyzing optical signals from the optical fibers to detect intrusion in the optical fibers; but up to now no system has been available for detecting intrusion into conductive cables.

As the fiber optic IDS security ends at the optical cable termination, the remaining conductive cable run to the desk, typically copper, is left unprotected and subject to potential tapping.

It is well known, by those skilled in the technology, that copper data pairs are easily tapped and the data stream monitored. One relatively simple non-interruptive tapping method involves placing a probe type coupler next the pair to be tapped. A small fraction of the data stream is picked up electrically from the pair, which is then amplified and monitored.

Other types of cable intrusion detection methods have been described in patent publications. These include:

U.S. Pat. No. 2,787,784, Meryman issued Apr. 2, 1957 Triboelectric Detecting System, describes a method of using a “noisy” cable to detect, amplify and alarm mechanical disturbances using a physically deformable triboelectric generating cable. The method required that certain insulated conductors within the cable are designed such that the insulation is applied loosely allowing mechanical movement between the conductor and the insulation which results in the triboelectric effect.

U.S. Pat. No. 4,374,299, Kincaid issued Feb. 15, 1983 Triboelectric Transducer Cable, describes a cable system whereby certain conductors and the surrounding loosely applied insulation are further optimized to enhance the triboelectric effect.

U.S. Pat. No. 5,446,446 Harman issued Aug. 29, 1995 Differential, multiple cell reflex cable intrusion detection system and method, discloses a type of coaxial cable intrusion detection system which includes a form of sense wire loosely through the dielectric. Movement, of the transducer cable results in movement of the sense wire relative to the outer conductor, causing corresponding changes in characteristic impedance of the sense wire which causes coupling between a carrier signal traveling the coax to couple to the sense wire. A receiver detects the sense wire signal and reports it as an intrusion. This method requires a coax cable configuration and a sense wire within the dielectric insulation.

Security system transmission line U.S. Pat. No. 4,710,753 Rich, et al issued Dec. 12, 1987 relates to a leaky cable intrusion detection system comprising a pair of spaced, parallel, buried, leaky coaxial cables. A radio frequency signal is applied to one of the cables, whereby an electromagnetic field outside said one cable is established, and a radio frequency signal from the field penetrates and is received from the other of the cables whereby disturbances in said field can be detected. This method involves two parallel RF transmission fines to detect intrusion into the space between them.

All publications, patents, and patent applications mentioned in this specification are herein incorporated by reference to the same extent as if each individual publication, patent, or patent application was specifically and individually indicated to be incorporated by reference.

### SUMMARY OF THE INVENTION

It is one object of the present invention to provide an arrangement for detecting movement of an element having longitudinal conductive elements.

According to the invention there is provided a method for monitoring movement of an element comprising:

providing a pair of conductive elements each extending along an extent of the element to be monitored

applying a DC potential difference between the conductive elements;

arranging the conductive elements with an intervening material therebetween such that the movement causes a change in capacitive coupling between the conductive elements so as to generate a changing voltage therebetween;

and detecting and monitoring the changing voltage for perturbations caused by the movement of the element.

In one embodiment the intervening material is a continuous dielectric material separating the two conductive elements.

In another different embodiment the intervening material separating the two conductive elements is not a continuous dielectric ut has varying capacitance along its length. The intervening material separating the two conductive elements can includes dissimilar materials such as air spaces across its thickness.

In one embodiment the element comprises a cable for monitoring movement of the cable. In this case both conductive elements can be located inside an outer cover of the cable. In this case the cable can form one of a plurality of cables contained inside an outer jacket and both conductive elements are inside the outer jacket. The conductive elements can however be placed in the interstices between the cables.

In another embodiment, the cable forms one of a plurality of associated cables and one of the pair of conductive elements is located within in one cable and one in another.

Typically the changing voltage forms a variable signal which is applied to an amplifier where the amplifier provides adequate gain while suppressing common mode noise on both conductive elements.

In this case preferably the DC potential difference is separated from the amplifier by a capacitor allowing the changing voltage to pass through the capacitor.

In some embodiments, the conductive elements form a conductor pair for transmitting data such as a balanced pair or a coax cable.

The monitoring of the movement provided by this invention can be used for many end uses. In a particularly preferred arrangement, the movement is monitored to detect movement indicative of an unauthorized intrusion. In this case typically the movement is monitored for intrusion signature patterns and an alarm signal is transmitted when an intrusion is suspected.

In order to process the varying voltage the monitoring system preferably acts by filtering a signal generated from the changing voltage by initiating a learning period to learn the environmental background disturbances over a period of time and then applying filtering algorithms to eliminate or reduce the background disturbances. The system may also filter a signal generated from the changing voltage by applying filtering algorithms to identify signals which are then correlated to the signature of an attempted intrusion while ignoring normal background mechanical disturbances.

Where used in communication systems, where dedicated conductive elements are not available, each conductive element can comprises a communication pair of wires of the system. In this case each of the pairs is at a common potential so that the potential difference is applied between both wires of one pair and both wires of the other pair.

In another option, there is provided a remote transfer cable connected at one end to the conductive elements and at the other end to control system for supplying the potential difference and for receiving the varying voltage for monitoring.

In another option the method includes monitoring a multitude of elements simultaneously wherein each element has a respective pair of conductive elements which are connected in parallel for common monitoring.

As another possible end use different from communication systems, the element forms a vibration sensor such as used for seismographic reporting or for monitoring of structural resonances.

The embodiment described herein discloses a novel and simpler method of metallic conductor cable intrusion detection. That does not require special sensing wires, transmission lines or loosely insulated conductors. In particular one embodiment described herein discloses employs standard insulated conductors designed for data and voice communication that are not suitable in the prior are detection schemes and are designed to minimize triboelectric effect.

### BRIEF DESCRIPTION OF THE DRAWINGS

One embodiment of the invention will now be described in conjunction with the accompanying drawings in which:

FIG. 1 is a schematic of a first embodiment of monitoring system using the method of the present invention in which a single pair of wires of a cable is monitored for movement.

FIG. 2 is a schematic of a second embodiment of monitoring system using the method of the present invention where two pairs of wires are used to provide the conductive elements.

FIG. 3 is a schematic of a third embodiment of monitoring system using the method of the present invention where a coupling cable is provided for remote monitoring.

FIG. 4 is a schematic of a fourth embodiment of monitoring system using the method of the present invention where two conductive elements are inserted into a bundle of cables with an outer jacket.

FIG. 5 is a schematic of a fifth embodiment of monitoring system using the method of the present invention where two a coaxial cable is monitored.

FIG. 6 is a schematic of a sixth embodiment of monitoring system using the method of the present invention where a series of cables are monitored in parallel.

FIG. 7 is a schematic of a seventh embodiment of monitoring system using the method of the present invention where a series of cables are remotely monitored in parallel.

In the drawings like characters of reference indicate corresponding parts in the different figures.

### DETAILED DESCRIPTION

Fundamental to the present invention is the application of an electric field between two parallel conductors that traverse the length of the cable and by monitoring changes in the voltage between the conductors as a result of the change in capacitance caused by movement in the cable. The voltage, charge and capacitance between the two conductors are related by:

V=Q/C

where:

V is the applied voltage between the conductors

Q is the charge

C is the capacitance between the conductors

As the charge is essentially constant with the applied voltage and the change in capacitance as a result of movement of the cable is quite small, the change in voltage across the conductors can be approximated by:

V=□C V/C

where:

V is the change in voltage between the two conductors and

C is the change in capacitance between the two conductors caused by movement of the cable

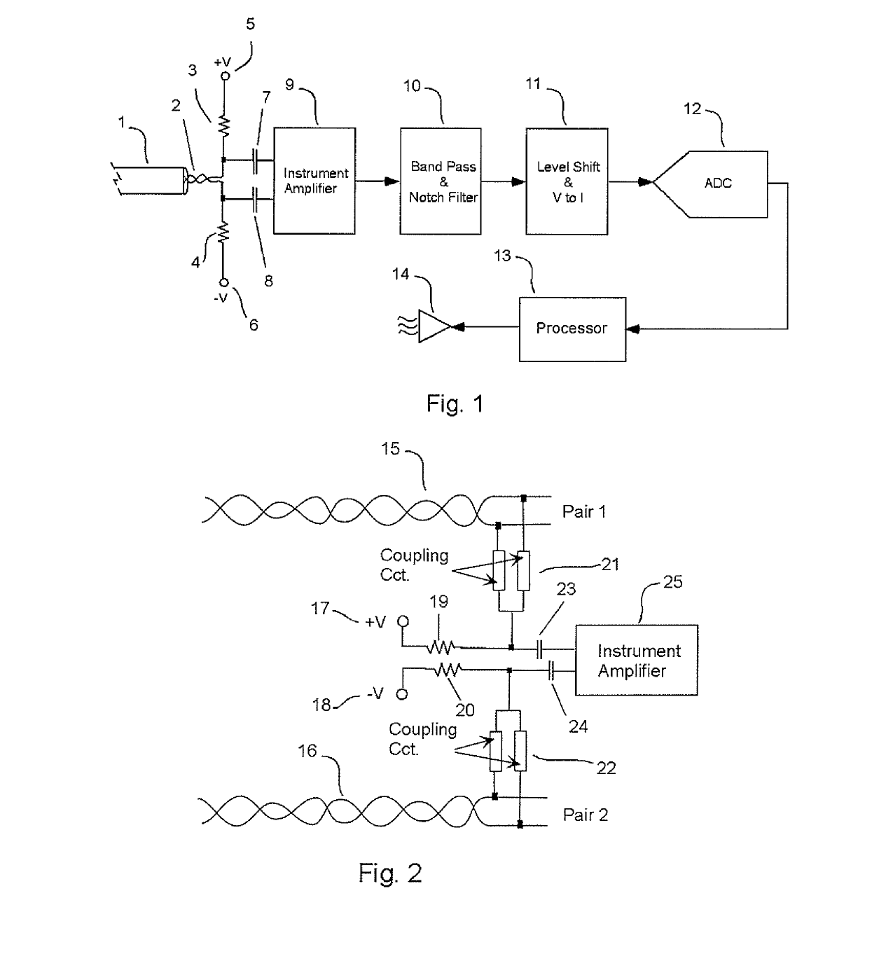

Referring to FIG. 1, a cable 1 containing a pair of metallic conductors 2 is connected to the input of a high impedance instrument amplifier 9 through coupling capacitors 7, 8. A DC bias voltage of 2V provided by plus and minus terminals 5 and 6 is placed across the conductor pair through coupling circuits provided by resistors 3 and 4. The conductive elements have an intervening material therebetween such that the movement in the cable 1 will cause a slight change in the capacitance between the two conductors 2 at the location of the movement which results in a corresponding change in voltage across the coupling circuits (resistors) 3, 4.

The voltage change, which is a varying electrical signal proportional to the mechanical disturbance of the cable, is then coupled to the input of instrument amplifiers 9 through the coupling capacitors 7, 8. The instrument amplifier 9 provides adequate gain while suppressing common mode noise. The resultant amplified signal is then fed to a filter stage 10 where unwanted noise and power line influences are further attenuated. The filtered signal is then feed to a level shift and voltage-to-current stage 11 Which conditions the analog signal and forwards it to the input of an analog to digital convertor (ADC) 12. The output of the ADC stage 12 is passed to the input of a computer processor 13. The computer based processor analyzes the disturbance signal for intrusion signature patterns and sends an alarm signal 14 when an intrusion is suspected.

The signal analysis system including the filters can be of the type used by the present Assignees in the above mentioned optical system and disclosed in one or more of the above patents. Once the signal from the sensing system is converted to a varying electrical signal, its processing to cancel unwanted noise and to extract a meaningful response is common between the conductive cables herein and the optical fibers used in the above documents.

In FIG. 1 the conductive elements 2 are spare conductors available within a cable to be monitored. These may also be used for data transmission or may be unused conductors. The pair 2 is typically a balanced pair of data transmission conductors of a conventional nature. In this case they are not surrounded by a continuous dielectric material but have individual jackets and potentially air spaces between them. However at each point along the pair there is a specific capacitance value while the conductors are at rest or at constant spacing between them. This capacitance value may, in the steady state, vary along the length of the conductors but remains constant unless motion causes a change in the capacitance value at one or more points or areas along the conductors.

It has been found that the change in capacitance is sufficient to generate a change in the voltage which can be measured and the resultant signal can be analyzed to produce meaningful data about movement of the conductors at points along their length. In particular, the data can be analyzed to provide information on movement of the cable indicative of an attempt by an unauthorized person to gain access to the cable and the data in the cable.

In telecommunications systems, the two conductors are typically a balanced pair and are referred to as “tip” and “ring” conductors

In the second embodiment of FIG. 2, there may be a case where no spare conductors are available in the cable to be monitored. In this case, and particularly with cables containing communication pairs 15 and 16, a third circuit can be derived from two other pairs. The third circuit, called a phantom circuit, can be used to monitor the cable for movement without degrading the normal telecom or data traffic on the other two pairs 15, 16. Both pairs 15, 16 are carrying telecom traffic that cannot be interfered with. To derive a third circuit from the other two, coupling circuits 21, 22 are placed as shown on the conductors of each pair. The coupling circuit 21, 22 provides a low pass connection to the conductors of both pairs, while providing a high impedance between the conductors of the pairs. The center point of the couplers is connected to the voltage sources 17, 18 through a coupling circuit such as resistors 19, 20. In this illustration both conductors of pair 15 are energized at +V 17 and both conductors of pair 16 are energized at −V 18. This results in a potential difference of 2V between the two pairs. This creates a third or virtual circuit between the two pairs. The two conductors of the third circuit are coupled to the input of the instrument amplifier 25 described above through coupling capacitors 23, 24. The third circuit, as connected, becomes a monitoring pair and movement in the cable will generate an electrical signal which can be analyzed as described above.

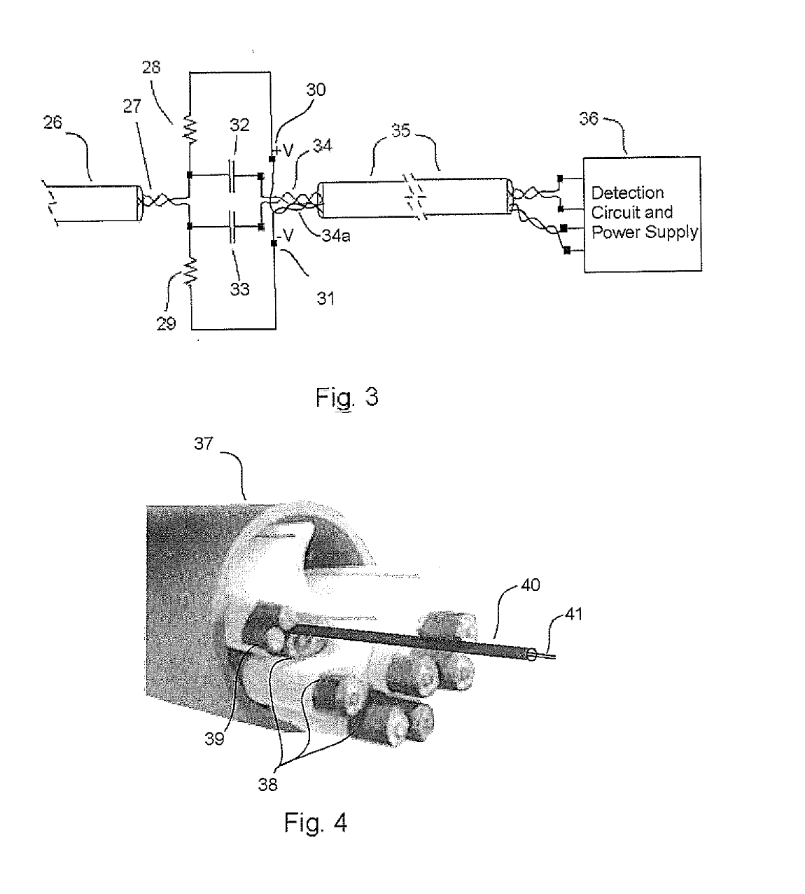

In some instances, the cable to be monitored for intrusion is remote from the monitoring system and it may be necessary to extend the monitoring circuit over a conductor pair where monitoring is not needed or not wanted. This can be accomplished as illustrated in FIG. 3.

The remote cable 26 to be monitored includes a pair of conductors 27 that is connected to a remote voltage supply 30, 31 through a coupling circuit 28, 29.

These connections energize the monitoring conductors to a voltage of 2V. Capacitors 32, 33 couple the varying component of the monitoring signal to the conductor pair 34, 34A leading to the monitoring system 36 over the connecting cable 35. As the coupling capacitors 32, 33 allow the monitored signal to pass over the conductor pair 34 while blocking the DC energizing current, the conductor pair 34, 34A leading to the monitoring system 36 is not monitored for intrusion. The remote voltage supply 30, 31 could also be provided by a second pair in the connecting cable 35 and supplied from the monitoring system 36.

The above descriptions detail how a cable can be monitored using a conductor pair contained within the cable. In another application, it may be desirable to monitor cables from an external location for any attempted intrusion. This can be done by locating a monitored cable in close proximity to the cable(s) to be monitored. Referring therefore to FIG. 4, a duct system 37 enclosing several bundles of cables 38 includes a monitoring cable 40 with monitoring conductors 41. The monitoring cable 40 is placed in the interstices of a selected cable bundle 39 or between to monitor that bundle for intrusion related disturbances. The individual cables themselves in the monitored bundle are not monitored individually but are monitored by the monitoring cable 40 placed within the bundle.

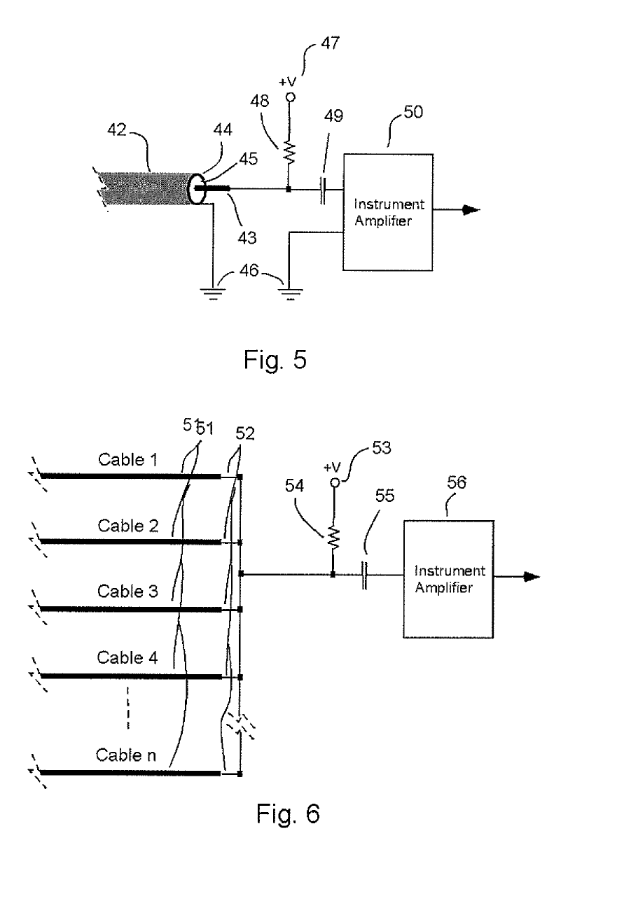

In a fifth embodiment, the monitoring conductors may form components of a coaxial pair. FIG. 5 shows an intrusion monitoring system using a coaxial pair 42, 43 of conductors in an unbalanced configuration. The coaxial pair has an inner conductor 43 surrounded by an outer conductor 44 with a dielectric material 45 in between the two conductors. In this case the dielectric material is continuous and constant along the length but still varies at points or areas along the cable as movement occurs. Both the outer conductor 44 and the input from the instrument amplifier are referenced to ground 46. The inner conductor 43 is energized to +V 47 through a coupling circuit 48. The variable portion of any disturbance signal is coupled to the input of the instrument amplifier through capacitor 49. The coaxial configuration is more immune to external electrical noise than a balanced pair of conductors and can provide significant improvement in the overall signal to noise ratio.

In a sixth embodiment, the intrusion monitoring system can be configured to monitor a multitude of cables simultaneously. As shown schematically in FIG. 6, a series of cables each formed by a balanced pair 51 numbered as cables 1 through to cable n each have their monitoring conductors 52 connected in parallel at the monitoring end. This type of connection is often referred to as a star connection. All of the monitoring pairs 52 are simultaneously energized by voltage +V 53 through coupling circuit 54. Mechanical disturbances in any or all of the cables will result in an electrical signal which is coupled to the instrument amplifier 56 through capacitor 55.

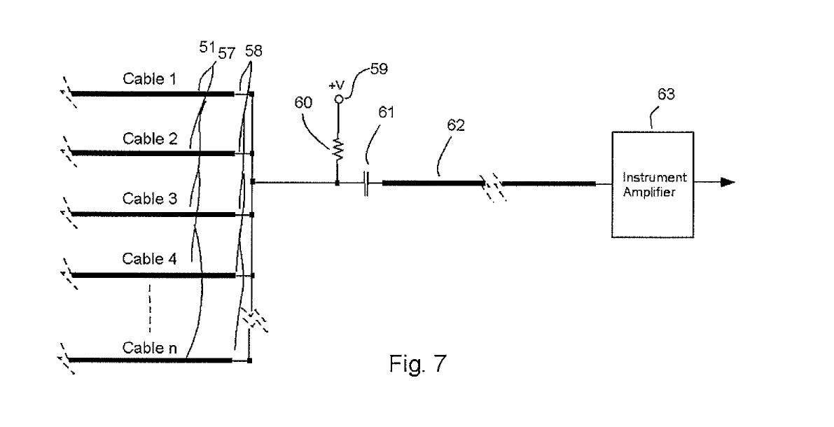

In some instances, the multitude of cables to be monitored for intrusion will be remote from the monitoring system and it may be necessary to extend the monitoring circuit over a conductor pair where monitoring is not needed or not wanted. This can be accomplished as illustrated schematically in FIG. 7. The cables to be monitored 57 have the monitoring conductors connected in a parallel star configuration 58 at a remote site. Located at the remote site is the energizing voltage source 59, coupling circuit 60 and DC blocking capacitor 61. The monitored signal is communicated to the intrusion monitoring system 63 over the conductors in a connecting cable 62 which is not monitored due to the lack of DC biasing in that section.

Additional Information:

This technique can be used as a room/building/campus wide vibration sensor for uses such as local or distributed seismographic reporting.

The seismographic sensor can communicate to a centralized location for data collection and analysis.

This technology can be used for eavesdropping and surveillance within the room/building/campus.

This technique can be used as a room/building/campus as well as infrastructure such as bridge wide vibration sensor for monitoring of structural resonances, alone or concurrent with network distribution.

Since various modifications can be made in my invention as herein above described, and many apparently widely different embodiments of same made within the spirit and scope of the claims without department from such spirit and scope, it is intended that all matter contained in the accompanying specification shall be interpreted as illustrative only and not in a limiting sense.

1. A method for monitoring movement of an element comprising:
providing a pair of conductive elements each extending along an extent of the element to be monitored
applying a DC potential difference between the conductive elements;
arranging the conductive elements with an intervening material therebetween such that the movement causes a change in capacitive coupling between the conductive elements so as to generate a changing voltage therebetween;
and detecting and monitoring the changing voltage for perturbations caused by the movement of the element.

2. The method according to claim 1 wherein the intervening material is a continuous dielectric material separating the two conductive elements.

3. The method according to claim 1 wherein the intervening material separating the two conductive elements has varying capacitance along its length.

4. The method according to claim 1 wherein the intervening material separating the two conductive elements includes dissimilar materials across its thickness.

5. The method according to claim 1 wherein the element comprises a cable for monitoring movement of the cable.

6. The method according to claim 5 wherein both conductive elements are located inside an outer cover of the cable.

7. The method according to claim 5 wherein the cable forms one of a plurality of cables contained inside an outer jacket and both conductive elements are inside the outer jacket.

8. The method according to claim 5 wherein the conductive elements are placed in the interstices between the cables.

9. The method according to claim 5 wherein the cable forms one of a plurality of associated cables and wherein one of the pair of conductive elements is located within in one cable and one in another.

10. The method according to claim 1 wherein the changing voltage forms a variable signal which is applied to an amplifier.

11. The method according to claim 10 wherein the amplifier provides adequate gain while suppressing common mode noise on both conductive elements.

12. The method according to claim 1 wherein the DC potential difference is separated from the amplifier by a capacitor allowing the changing voltage to pass through the capacitor.

13. The method according to claim 1 wherein the conductive elements form a conductor pair for transmitting data.

14. The method according to claim 13 wherein the conductive elements form a balanced pair.

15. The method according to claim 13 wherein the conductive elements form a coax cable.

16. The method according to claim 1 wherein the movement is monitored to detect movement indicative of an unauthorized intrusion.

17. The method according to claim 16 wherein movement is monitored for intrusion signature patterns and an alarm signal is transmitted when an intrusion is suspected.

18. The method according to claim 16 including filtering a signal generated from the changing voltage by initiating a learning period to learn the environmental background disturbances over a period of time and then applying filtering algorithms to eliminate or reduce the background disturbances.

19. The method according to claim 16 including filtering a signal generated from the changing voltage by applying filtering algorithms to identify signals which are then correlated to the signature of an attempted intrusion while ignoring normal background mechanical disturbances.

20. The method according to claim 1 wherein each conductive element comprises a communication pair of wires.

21. The method according to claim 20 wherein each of the pairs is at a common potential so that the potential difference is applied between both wires of one pair and both wires of the other pair.

22. The method according to claim 1 wherein there is provided a remote transfer cable connected at one end to the conductive elements and at the other end to control system for supplying the potential difference and for receiving the varying voltage for monitoring.

23. The method according to claim 1 including monitoring a multitude of elements simultaneously wherein each element has a respective pair of conductive elements which are connected in parallel for common monitoring.

24. The method according to claim 1 wherein the element forms a vibration sensor.

25. The method according to claim 1 wherein the vibration sensor is used for seismographic reporting.

26. The method according to claim 1 wherein the vibration sensor is used for monitoring of structural resonances.
